(19) United States
(12) Patent Application Publication
(10) Pub. No.: US 2016/0118556 A1
(43) Pub. Date: Apr. 28, 2016

(54) LIGHT-EMITTING DEVICE WITH LIGHT SCATTERING LAYER

(71) Applicant: Avago Technologies General IP (Singapore) Pte.Ltd., Singapore (SG)

(72) Inventors: Sook Choo Lim, Penang (MY); Lee Yen Jenifer Ooi, Penang (MY); Joh Joh Ng, Berak (MY)

(21) Appl. No.: 14/526,229

(22) Filed: Oct. 28, 2014

(51) Int. Cl. H01L 33/60; H01L 33/58; H01L 25/075; H01L 33/52

(52) U.S. Cl. CPC H01L 33/60; H01L 33/52; H01L 33/58; H01L 25/0753

(57) ABSTRACT

In one embodiment, a light-emitting device having a reflector, a light source die, a light scattering member, a first encapsulant, and a second encapsulant is disclosed. The light scattering member may be configured to scatter light emitted from the light source die, before the light being transmitted into the second encapsulant where a lens surface is configured to collimate the light towards a first direction. The light scattering member may be light-scattering particles distributed uniformly within the first encapsulant, a roughened surface of the first encapsulant, and a deposited light scattering layer on the first encapsulant, air bubbles, or a substantially flat layer. The light scattering member may be provided outside a reflector cup.

### BACKGROUND

A light-emitting diode (referred to hereinafter as LED) represents one of the most popular light-emitting devices today. In recent years, the luminous efficacy of LEDs, defined in lumens per Watt, has increased significantly from 20 lumens per Watt (approximately the luminous efficacy of an incandescent light bulb) to over 500 lumens per Watt, which greatly exceeds the luminous efficacy of a fluorescent light at 60 lumens per Watt. In addition to the luminous efficacy, LEDs may be superior or preferable compared to traditional light sources because of the small form factor. Due to the small form factor, an optical lens may be placed close to the light sources. Various optical designs that were not possible with traditional light sources may become possible for the LEDs. With new optical designs, LEDs may become one of the most appealing light sources nowadays. As a result, LEDs are finding their ways to almost all applications that require light.

One application for LEDs is infotainment display systems. These large-scale display systems may have thousands of LEDs arranged in a two dimensional plane to display information, advertisement video clips and other types of data. Nowadays, infotainment display systems are displays commonly used in stadiums, football fields, or even on the streets in major cities. LEDs used in these display systems are usually high power LEDs. Usually, color and brightness consistency requirements in these LEDs are demanding. In addition, LEDs used in these display systems are required to have a large viewing angle.

### BRIEF DESCRIPTION OF THE DRAWINGS

Illustrative embodiments by way of examples, not by way of limitation, are illustrated in the drawings. Throughout the description and drawings, similar reference numbers may be used to identify similar elements. The drawings may be simplified illustrative views rather than precise engineering drawings. The drawings are for illustrative purpose to assist understanding and may not necessarily be drawn per actual scale.

FIG. 1 shows an illustrative block diagram of a light-emitting device having a light scattering member;

FIG. 2A illustrates a cross-sectional view of a light-emitting device having light scattering particles distributed within a first encapsulant;

FIG. 2B illustrates a top view of the light-emitting device shown in FIG. 2A;

FIG. 2C illustrates light scattering particles provided within the first encapsulant;

FIG. 2D illustrates viewing angle of the light-emitting device shown in FIG. 2A;

FIG. 3A illustrates a cross-sectional view of a light-emitting device with a light scattering member with non-homogeneous profile;

FIG. 3B illustrates a top view of the light-emitting device shown in FIG. 3A;

FIG. 3C illustrates light scattering particles having a concentration portion provided within a first encapsulant;

FIG. 4A illustrates a cross-sectional view of a light-emitting device with a light scattering layer;

FIG. 4B illustrates a roughening surface of the light scattering layer;

FIG. 5 illustrates a light scattering layer comprising a plurality of air bubbles;

FIG. 6A illustrates a cross-sectional view of a light-emitting device with a light scattering encapsulant having a flat surface;

FIG. 6B illustrates a top view of the light-emitting device shown in FIG. 6A;

FIG. 7A illustrates a cross-sectional view of a light-emitting device with improved light emission uniformity;

FIG. 7B illustrates a cross-sectional view of a reflector cup and a light scattering layer of the light-emitting device shown in FIG. 7A; and

FIG. 8 illustrates a cross-sectional view of a display system.

### DETAILED DESCRIPTION

Light-emitting devices may be implemented using various packaging technologies such as a plastic leaded chip carrier (herein after PLCC) package, a ball grid array package (herein after BGA), a pin grid array package (herein after PGA), a quad flat pack (herein after QFP), a printed circuit board (herein after PCB) package and so on. Certain packages, for example PLCC packages, may comprise a lead frame over a molded polymer material such as Polyphthalamide (herein after PPA), Polyamide or Epoxy resin encapsulant like MG 97. For surface mount type, leads extending from the lead frame may be bent so that the light-emitting devices can be soldered on a substrate without through-holes. Light-emitting devices based on other packaging technologies such as a BGA and PGA may comprise a substrate having conductive traces without a lead frame. In this specification, various embodiments of Lamp-LED are illustrated. However, the teaching throughout the specification about an LED may be applicable to a light source packaging, including at least all various types of packaging technologies discussed above. In addition, a light-emitting device should not be limited to devices for lighting purposes, but also other optical device that may emit a radiation of invisible light. For example, a light-emitting device may comprise a proximity sensor, an encoder or other optical device involving an emitter configured to emit a visible or invisible light.

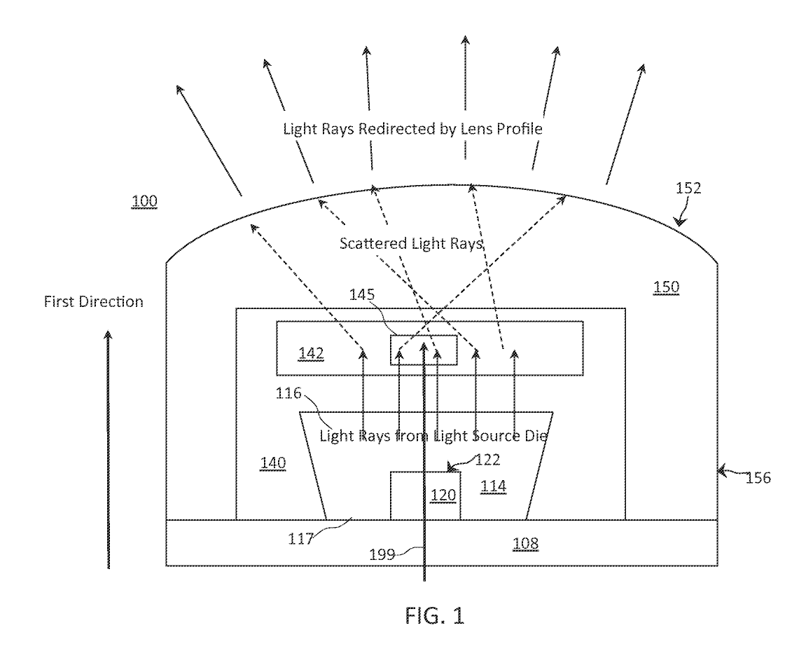

FIG. 1A shows an illustrative block diagram of a light-emitting device 100. The light-emitting device 100 may comprise a light source die 120, a reflector cup 114, a first encapsulant 140 encapsulating the light source die 120 and at least partially the reflector cup 114, a light scattering member 142, and a second encapsulant 150. The second encapsulant may be entirely encapsulating the first encapsulant 140 and the reflector cup 114. Optionally, the light-emitting device 100 may comprise a substrate 108 depending on the type of packages. Lamp LED type packaged light-emitting device 100 do not have a substrate but the entire light-emitting device 100 may be provided on an external printed circuit board.

The reflector cup 114 may be tapered having a narrow end 117 and a wider top end 116. The reflector cup 114 may be extending longitudinally along a center axis 199 that point towards a first direction. The reflector cup 114 may comprise an opening at the top end 116. Both the opening and the top end 116 may be facing the first direction whereas the narrow end 117 may be located on an opposing side as shown in FIG. 1. The light source die 120 may be provided within the reflector cup 114. The reflector cup 114 may be configured to direct light emitted from the light source die 120 towards the first direction.

The reflector cup 114 may comprise reflector surfaces. The light source die 120 may be attached on a surface at the narrow end 117 of the reflector cup 114. The reflector cup 114 may be formed within a lead frame (not shown) for a lamp LED, or alternatively, the reflector cup 114 may be defined by surfaces of the substrate 108 and/or surfaces of a body (not shown). A body of a light-emitting device (not shown) may be a primary structure for providing support to the light source die 120.

The light source die 120 may be a light source or a radiation source such as an LED configured to emit radiation. The light source die 120 may be configured to emit electromagnetic radiation waves that may are invisible to human eyes such as infrared, ultra-violet or similar radiation having some other invisible wavelength. Alternatively, the light source die 120 may be configured to emit electromagnetic radiation of a visible wavelength. The light source die 120 may be coupled with the reflector cup 114 and may be configured to emit light towards the first direction along the center axis 199.

The first encapsulant 140 may be substantially transparent. In one embodiment, the first encapsulant 140 may have approximately more than ninety percent of transmissivity. The first encapsulant 140 may comprise substantially silicone material, epoxy or other substantially transparent material. The first encapsulant 140 may be encapsulating the light source die 120. The first encapsulant 140 may be encapsulating the entire reflector cup 114 or in another embodiment, the first encapsulant 140 may be encapsulating partially the reflector cup 114.

The light scattering member 142 may be provided within the first encapsulant 140. Specifically the light scattering member 142 may be integrally formed within the first encapsulant 140. The light scattering member 142 may be encapsulated entirely within the first encapsulant 140. In one embodiment, the light scattering member 142 may comprise a roughened surface of the first encapsulant 140. Optionally, the light scattering member 142 may further comprise air bubbles trapped on the roughened surface of the first encapsulant 140.

In another embodiment, the light scattering member 142 may comprise light scattering particles that are substantially uniformly distributed within the first encapsulant 140. The light scattering member 142 may be formed on the lens surface of the first encapsulant 140 may comprise a lens surface. In yet another embodiment, the light scattering member 142 may comprise a plurality of reflective particles encapsulated within the first encapsulant 140. The reflective particles may be a plurality of metallic particles having irregular shapes so as to scatter light incident on the first encapsulant 140 in a substantially random fashion.

As illustrated above, there may be many ways to configure a light scattering member 142. Further details of the light scattering member 142 will be discussed in various embodiments illustrated in subsequent drawings.

Optionally, the light scattering member 142 may comprise a high-density area 145. The area outside the high-density area 145 may be a low-density area relative to the high-density area 145. The high-density area 145 may be characterized by its ability to scatter light more as compared to the low-density area of the light scattering member 142. The high-density area 145 may be a center portion of the light scattering member 142 that is arranged approximating the light source die 120. In one embodiment, the light source die 120 may have a light-emitting surface 122 and the high-density area 145 may have an area substantially similar to an area of the light-emitting surface 122. In yet another embodiment, the high-density area may have an area approximately less than 120% of the area of the light-emitting surface 122 but larger than the area of the light-emitting surface 122. In yet another embodiment, the high-density area 145 may have an area smaller than an area of the opening of the reflector cup 114 located at the top end 116 but larger than the area of the light-emitting surface 122.

The second encapsulant 150 may comprise a lens surface 152 configured to collimate light scattered by the light scattering member 142. As shown in FIG. 1, the light scattering member 142 may be formed between the lens surface 152 and the light source die 120. The reflector cup 114 may be configured to direct light such that light emitted from the light source die 120 may be visible within a first range of viewing angle. The shape of the reflector cup 114, and the curvature of the lens surface 152 of the second encapsulant 150 may determine the first range of viewing angle. By employing the light scattering member 142 that is configured to scatter light, the light emitted from the light-emitting device 100 may be visible within a second range of viewing angle that is relatively larger than the first range of viewing angle. The second encapsulant 150 may be beneficial and serves two functionalities. First, the second encapsulant 150 may be surrounding and encapsulating the light scattering member 142, the first encapsulant 140 and the reflector cup 114 so as to provide protection from external forces or corrosions caused externally. Second, the lens surface 152 of the second encapsulant 150 may be configured to collimate light that has been scattered to achieve a desired viewing angle.

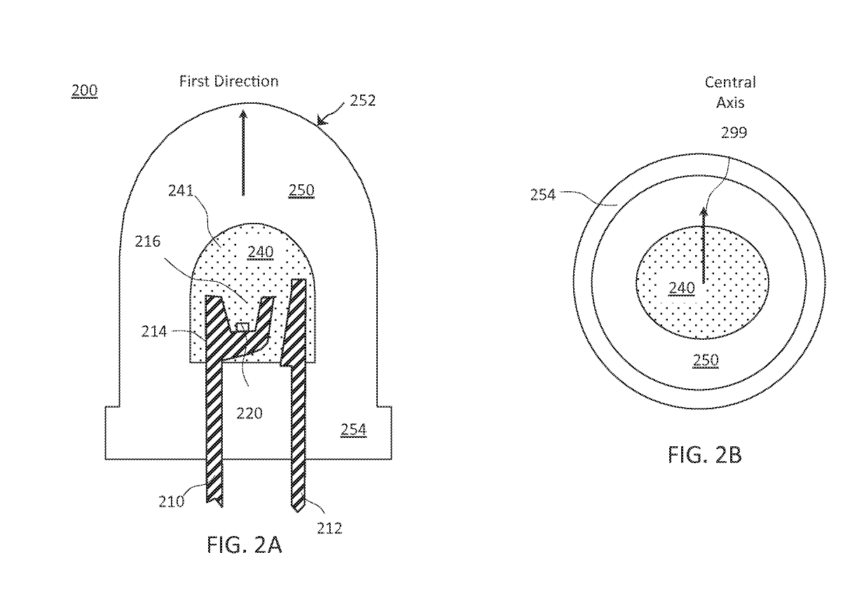

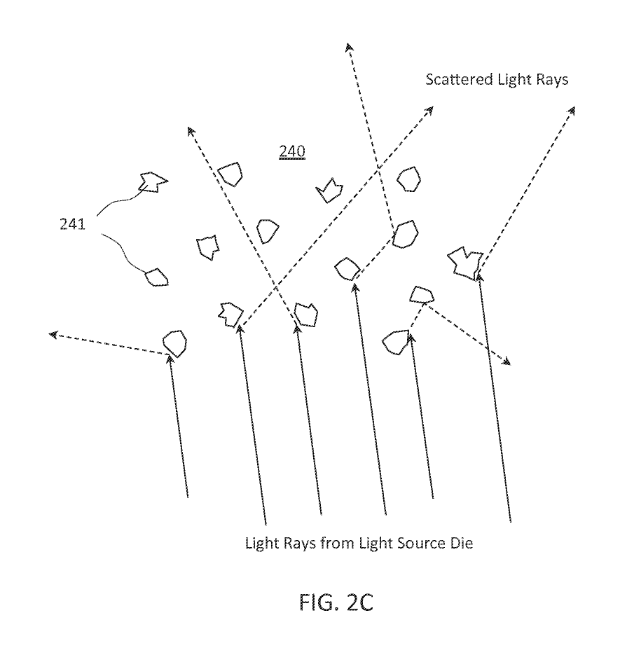

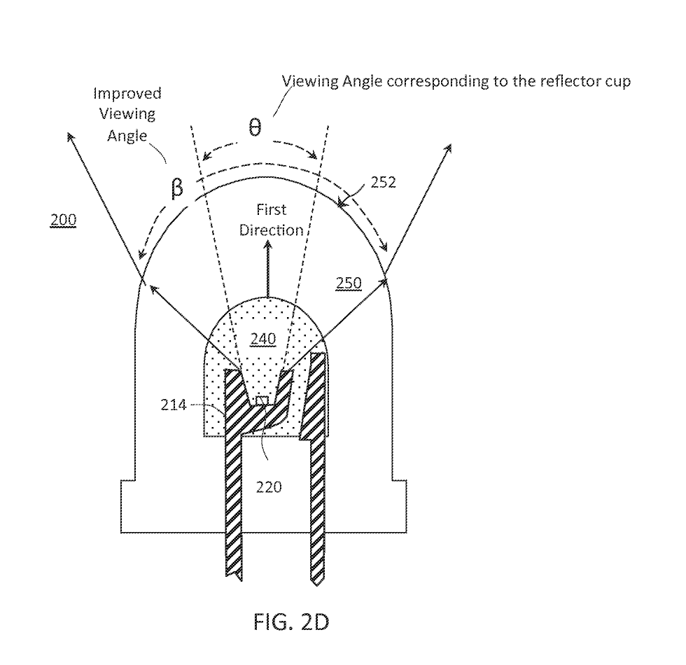

FIG. 2A illustrates a cross-sectional view of a light-emitting device 200. A top view of the light-emitting device 200 is shown in FIG. 2B. The light-emitting device 200 may comprise a plurality of conductors 210, 212, a reflector cup 214, a light source die 220, a first encapsulant 240, a plurality of light particles 241 and a second encapsulant 250. A shown in FIG. 2B, the first encapsulant 240, and the second encapsulant 250 may be concentric. More specifically, the first encapsulant 240 and the second encapsulant 250 may be coaxially aligned around a center axis 299. The first encapsulant 240 with the light scattering particles 241 distributed therein may be referred as a light scattering encapsulant. The second encapsulant 250 may have a base portion 254. “Conductors” 216, 217 as used herein in reference to the light-emitting device 200 may refer to what can electrically connect the light source die 220 to an external power source (not shown).

The light-emitting device 200 shown in FIG. 2A may be a lamp LED, and the plurality of conductors 210, 212 may comprise two leads 210, 212 encapsulated partially by the first encapsulant 240 and the second encapsulant 250. For a lamp LED, PLCC package or other packages formed using a molding process, the plurality of conductors 210, 212 may be leads forming part of lead frames but in other packaging technologies, for example printed circuit boards, the plurality of conductors 210, 212 may be electrically conductive traces formed on the PCBs. The scope of the invention should not be limited to any specific forms illustrated, but should be taken into consideration various other technologies, other forms of packaging either presently available, or developed in future.

In the embodiment shown in FIG. 2A, the plurality of conductors 210, 212 may be made of electrically and thermally conductive material, such as steel, copper, metal or a metal alloy, a metal compound or other similar material. The plurality of conductors 210, 212 may be formed using any conventional stamping, cutting, etching or other similar process that is known in the art. For surface mount purposes, the plurality of conductors 210, 212 may be bent to define a bottom portion for attaching to external surfaces (not shown). In the embodiment shown in FIG. 2A, one of the leads 210 may be configured to form the reflector cup 214 whereas the other one of the leads 212 may be configured to receive a wire bond (not shown) coupling to the light source die 220.

A “body” as used herein in reference to a component of a light-emitting device 200 may refer to a respective primary structure, which provides structural support for other components of the light-emitting device 200. In the embodiment, shown in FIG. 2A, the body may be the second encapsulant 250 having a base portion 254 that may be supported on an external substrate. In anther embodiment, the body may be a substrate such as a PCB. Each body may be a respective integral single piece structure. The body may be formed using an opaque material such as PPA, polyamide, epoxy resin, plastic and other similar material. The body may be formed encapsulating or surrounding the plurality of conductors 210, 212 using an injection mold or other similar process.

As shown in FIG. 2A, a portion of the plurality of conductors 210 may be made larger and may form the reflective cup 214. The reflector cup 214 may comprise an opening 216 located on a top end of the reflector cup 214. The reflector cup 214 may be shaped so as to direct light towards a first direction. The opening 216 of the reflector cup 214 may be configured to allow light to be transmitted towards the first direction. The first encapsulant 240 may comprises light scattering particles 241 as shown in FIG. 2C.

FIG. 2C illustrates light scattering particles 241 provided within the first encapsulant 240. The first encapsulant 240 may be substantially translucent. The light scattering particles 241 may be metallic materials having irregular shape. The light scattering particles 241 may be uniformly distributed within the first encapsulant 241 and integrally formed within the first encapsulant 241. As illustrated in FIG. 2C, light emitted from the light source die 220 may be scattered in a random manner to various directions. The first encapsulant 240 and the light scattering particles 241 may be entirely surrounded within the second encapsulant 250. The second encapsulant 250 may have a lens surface 252. The lens surface 252 may be configured to collimate light transmitted into the second encapsulant 250 from the first encapsulant 240 towards the first direction in a predetermined manner. The first encapsulant 240 and the second encapsulant 250 may have substantially similar material so as to minimize stress caused by thermal mismatch. The first encapsulant 240 and the second encapsulant 250 may have substantially similar coefficient of thermal expansion.

FIG. 2D illustrates viewing angle of the light-emitting device 200 shown in FIG. 2A. Without the light scattering particles 241, the light-emitting device 200 may have a viewing angle θ that corresponds to the shape of the reflector cup 214. As shown in FIG. 2D, the viewing angle θ may be defined by the curvature of the reflector cup 214. However, as the light emitted by the light source die 220 may be scattered prior to entering the second encapsulant 250, the effective viewing angle β of the light-emitting device 200 may be significantly improved. As shown in FIG. 2D, the effective viewing angle β may be substantially larger compared to the original viewing angle θ had the light scattering particles 241 not added. The effective viewing angle β may be adjusted further by the curvature of the lens surface 252.

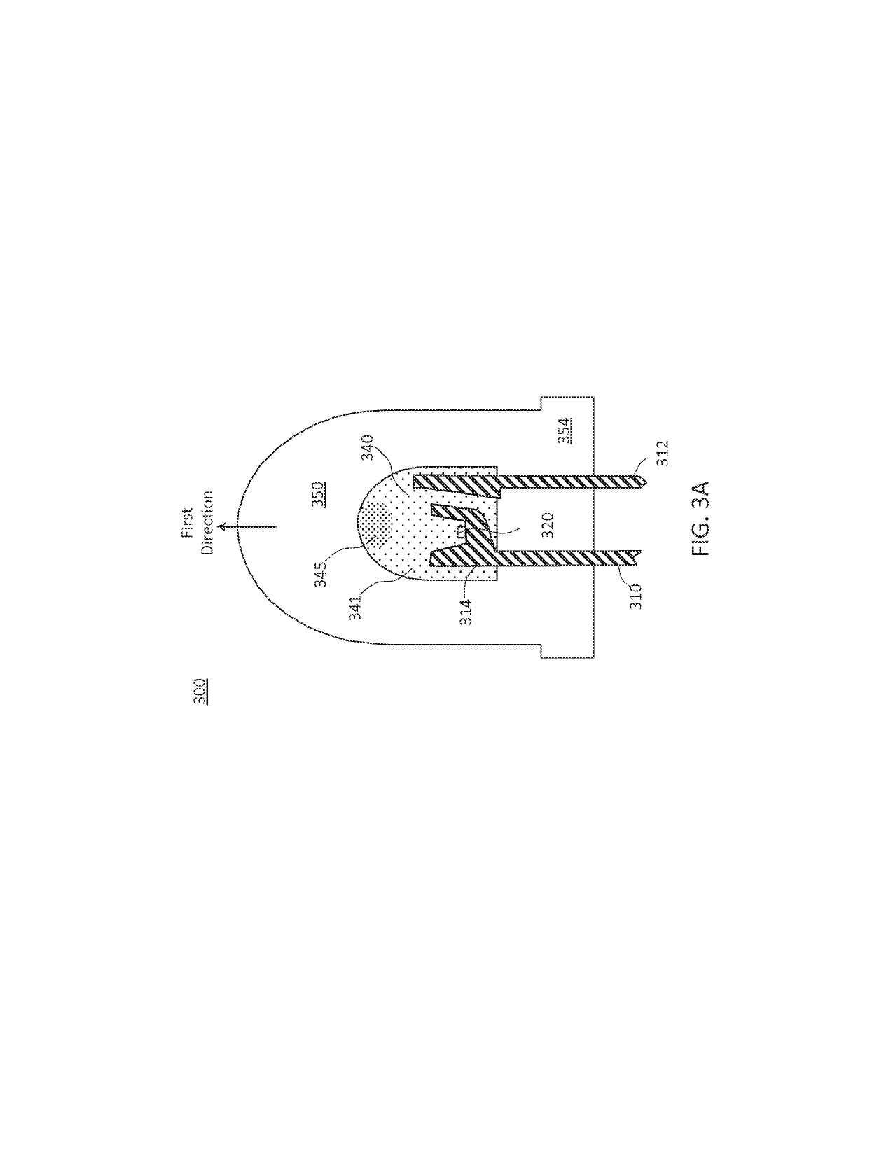

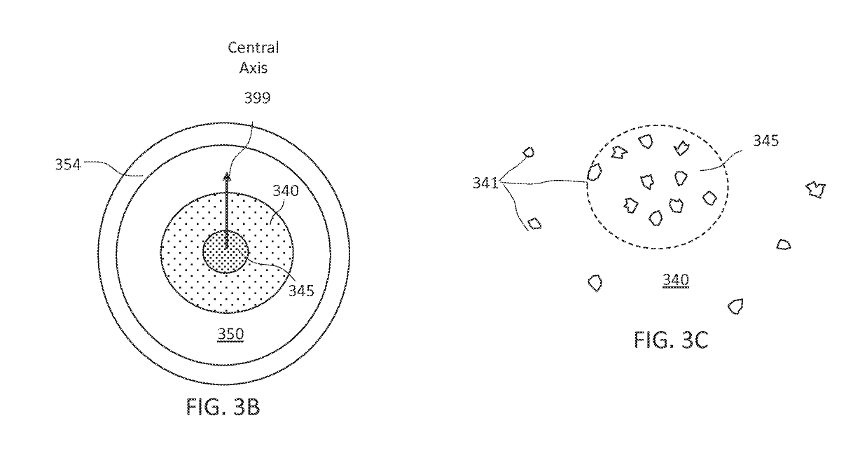

FIG. 3A illustrates a cross-sectional view of a light-emitting device 300. FIG. 3B illustrates a top view of the light-emitting device 300 shown in FIG. 3A. The light-emitting device 300 may comprise a plurality of conductors 310, 312, a reflector cup 314, a light source die 320, a first encapsulant 340, light scattering particles 341 distributed within the first encapsulant 340, and a second encapsulant 350. The first encapsulant 340 with the light scattering particles 341 distributed therein may be referred as a light scattering encapsulant 340. The second encapsulant 350 may have a base portion 354. The light-emitting device 300 may be substantially similar to the light-emitting device 200 but may differ at least in that the light-emitting device 300 comprises a high-density portion 345. As shown in FIG. 3B, the first encapsulant 340, the second encapsulant 350 and the high-density area 345 may be concentric. More specifically, the first encapsulant3, the second encapsulant 350 and the high-density area 345 may be coaxially aligned around a center axis 399.

Unlike the light-emitting device 200 shown in FIG. 2A, the scattering encapsulant 340 of the light-emitting device 300 shown in FIG. 3A may have a non-homogenous profile. The light scattering particles 241 of the light-emitting device 200 shown in FIG. 2A may be substantially uniformly distributed, but the light scattering particles 341 of the light-emitting device 300 shown in FIG. 3A may have a high-density area 345. FIG. 3C illustrates light scattering particles 341 having a concentrated portion provided within a first encapsulant 340. Outside the high-density area 345, the light scattering particles 341 may be uniformly distributed. The high-density area 345 may comprise at least two times more light-scattering particles per unit area compared to the area outside the high-density area 345.

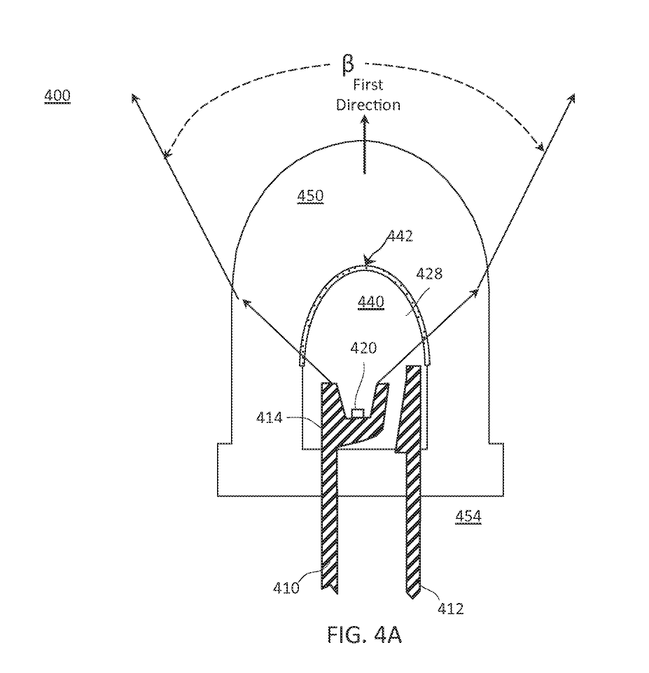

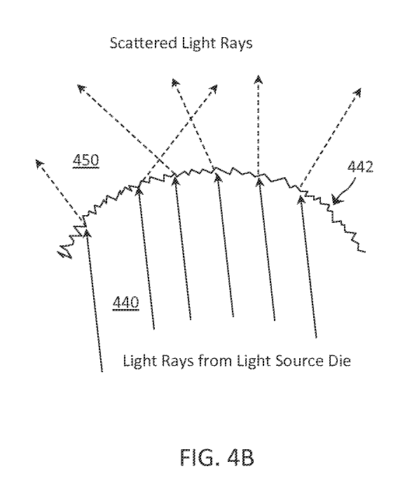

FIG. 4A illustrates a cross-sectional view of a light-emitting device 400. The light-emitting device 400 may comprise a plurality of conductors 410, 412, a reflector cup 414, a light source die 420, a first encapsulant 440, a light scattering layer 442, and a second encapsulant 450. The light-emitting device 400 may be substantially similar to the light-emitting device 300 but may differ at least in that the light-emitting device 400 comprises a light scattering layer 442 instead of light scattering particles 341 distributed within the first encapsulant 340 as shown in FIG. 3A.

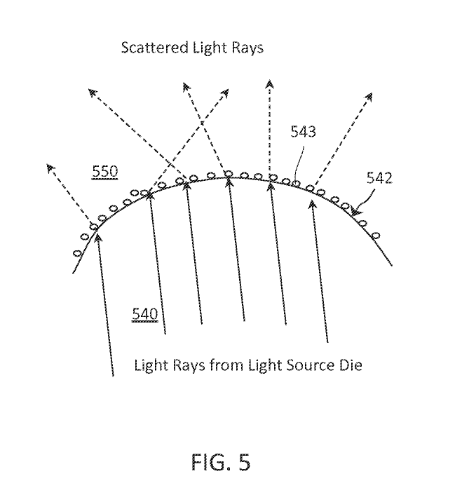

The first encapsulant 440 may be formed integrally with the light scattering layer 442. For example, the light scattering layer 442 may be a roughened surface of a surface of the first encapsulant 440. Alternatively, the light scattering layer 442 may be a layer with light scattering particles (not shown) deposited on the first encapsulant 440. The second encapsulant 450 may have a base portion 454. FIG. 4B illustrates a roughening surface of the light scattering layer 442. As shown in FIG. 4B, the roughened layer 442 may be configured to scatter light in a random manner such that viewing angle β of the light-emitting device may be improved. The improved viewing angle β may be substantially larger compared to the original viewing angle θ if the light scattering layer 442 is not added. The light scattering layer 442 may have a portion with high-density to scatter light more than other area as illustrated in previous embodiments. Alternatively, the light scattering layer 442 may be formed outside the first encapsulant 440 as shown in FIG. 5.

FIG. 5 illustrates a light scattering layer 542 comprising a plurality of air bubbles 543 instead of a roughened surface 442 shown in FIG. 4B. The air bubbles 543 may be configured to scatter light in a way substantially similar to the roughened surface. The layer of higher concentration of air bubbles 543 may be achieved by using an untreated epoxy prior to the encapsulating the first encapsulant 540 with the second encapsulant. As shown in FIG. 5, the air bubbles 543 may be formed at the surface near the first encapsulant 540.

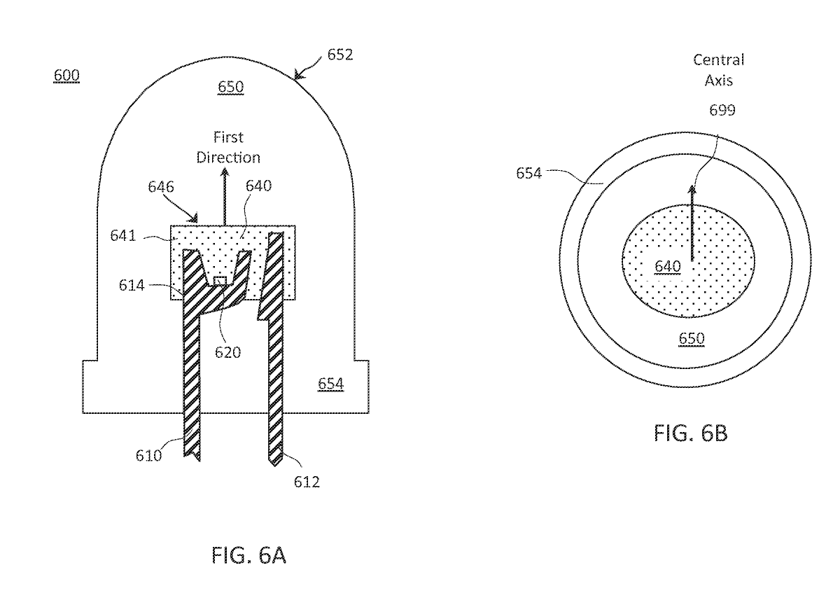

FIG. 6A illustrates a cross-sectional view of a light-emitting device 600. A top view of the light-emitting device 600 is shown in FIG. 6B. The light-emitting device 600 may comprise a plurality of conductors 610, 612, a reflector cup 614, a light source die 620, a first encapsulant 640, a light scattering particles 641 substantially uniformly distributed within the first encapsulant 640, and a second encapsulant 650. The light-emitting device 600 may be substantially similar to the light-emitting device 200 may differ at least in that the light-emitting device 600 comprises flat surface 642 instead of a curvature surface facing the first direction. Comparing to the curvature surface as shown in the embodiment shown in FIG. 2A, the flat surface 646 of the first encapsulant 650 does not collimate light. As a result, the viewing angle of the light-emitting device 600 may be improved compared to the light-emitting device 200 shown in FIG. 2A. As shown in FIG. 6B, the first encapsulant 640, and the second encapsulant 650 may be concentric. More specifically, the first encapsulant 650 and the second encapsulant 650 may be coaxially aligned around a center axis 699.

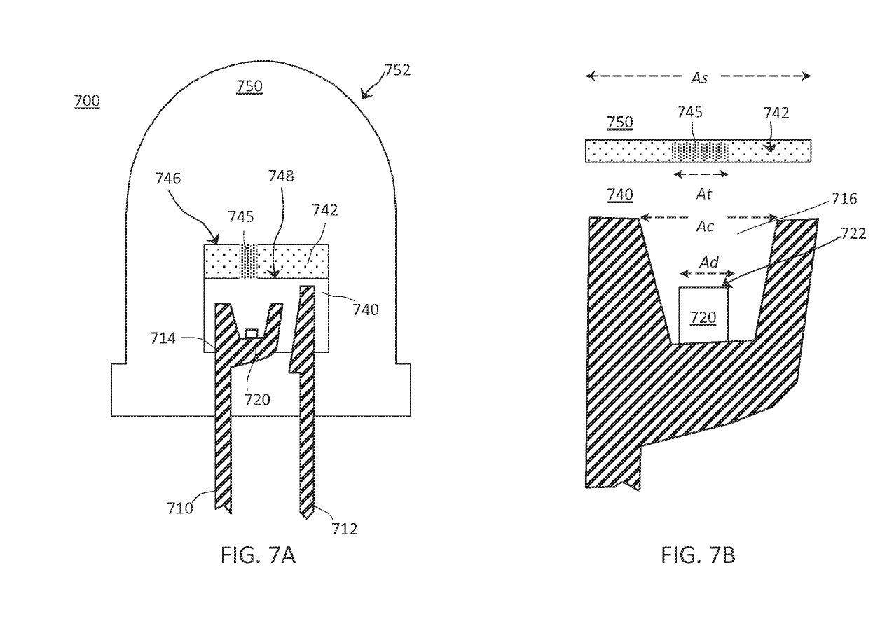

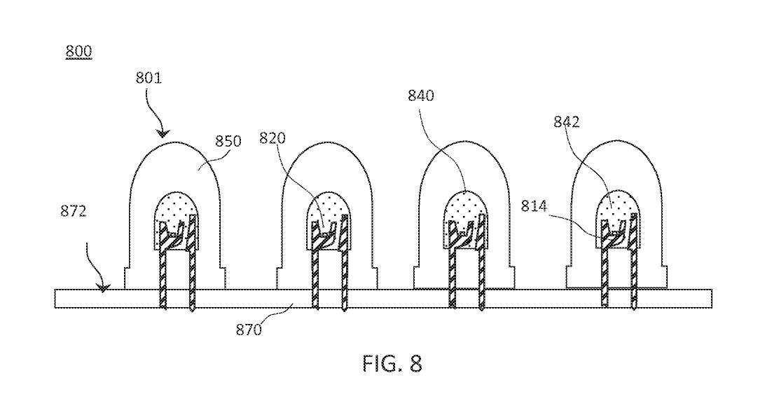

FIG. 7A illustrates a cross-sectional view of a light-emitting device 700. The light-emitting device 700 may comprise a plurality of conductors 710, 712, a reflector cup 714, a light source die 720, a first encapsulant 740, a light scattering layer 742 having light scattering particles 741 substantially uniformly distributed within the light scattering layer 742, a high-density area 745 and a second encapsulant 750.

Similar to previous embodiments, the reflector cup 714 may be configured to direct light towards a first direction. The light source die 720 may be attached within the reflector cup 714. The first encapsulant 740 may be encapsulating the light source die 720 and at least partially the reflector cup 714. The second encapsulant 750 may be surrounding and encapsulating the light scattering layer 742, the first encapsulant 740 and the reflector cup 714. The second encapsulant 750 may be configured to cover and to protect the light scattering layer 742, the first encapsulant 740 and the reflector cup 714 from external forces or corrosions caused externally. In addition, the second encapsulant 750 may comprise a lens surface 752 configured to collimate light that has been scattered to achieve a desired viewing angle.

However, unlike previous embodiment shown in FIG. 2A and FIG. 3A, the light scattering layer 742 may be formed adjacent to the first encapsulant 740, and not integrally with the first encapsulant 740. The light-emitting device 700 may be substantially similar to the light-emitting device 300 shown in FIG. 3A but may differ at least in that the light scattering layer 742 of the light-emitting device 700 may be a substantially thin flat layer instead of being uniformly distributed within the first encapsulant 340. In addition, the light scattering layer 742 may have a substantially flat surface 746 facing the first direction and an opposing flat surface 748 facing the light source die 720, i.e. an opposing direction of the first direction. As shown in FIG. 7A, the substantially flat surface 746 and the opposing flat surface 748 may be substantially perpendicular relative to the first direction.

The opposing flat surface 648 may be in direct contact with the first encapsulant 740 whereas the substantially flat surface 746 may be in direct contact with the second encapsulant 750. In contrast, the light-emitting device 200 comprises a curvature surface provided in the first encapsulant 240. Comparing to the curvature surface as shown in the embodiment shown in FIG. 2A, the flat surfaces 746, 748 of the light scattering layer 742 do not collimate light. As a result, the viewing angle of the light-emitting device 700 may be wider compared to the light-emitting device 200 shown in FIG. 2A. In addition, the light-scattering layer 742 has a substantially uniform thickness. The substantially uniform thickness of the light scattering layer 742 may ensure light uniformity as light ray is transmitted through substantially equal thickness of the light-scattering layer 742 prior to entering the second encapsulant 750.

FIG. 7B illustrates a cross-sectional view of the reflector cup 714 and the light scattering layer 742 of the light-emitting device 700 shown in FIG. 7A. The light source die 720 may have a light-emitting surface 722. The light-emitting surface 722 may have an area Ad. The light scattering layer 742 may have a high-density area 745 formed approximating and opposing the light-emitting surface 722 of the light source die 720. The high-density area 745 may have an area At. The light source die 720 may be provided within the reflector cup 714 having an opening 716 at the top end. The opening may have an area Ac. The area Ad of the light-emitting surface 722, the area At of the high-density area 745 and the area of Ac of the opening 716 of the reflector cup 714 may be measured planarly perpendicular to the first direction. The area At of the high-density area 725 may be at least the same size as the area Ad of the light source die 720. In another embodiment, the area At of the high-density area 725 may be approximately 120% of the area Ad of the light source die 720. The specific sizes of the high-density area 745. However, the area At of the high-density area 725 may be substantially less than of the area Ac of the opening 716 of the reflector cup 714. This may ensure that light is not scattered unnecessarily and high light output of the light-emitting device 700.

FIG. 8 illustrates a cross-sectional view of a display system 800. The display system 800 may be a large scale infotainment display systems used in stadiums, streets or other locations to display information or advertisement to the public. The display system 800 may comprise a substrate 870 having a first surface 872, and a plurality of light-emitting devices 801 arranged systematically in a two dimensional plane. The plurality of light-emitting devices 801 may the light-emitting devices 100, 200, 300, 400, 600 and 700 shown in previous embodiments. Each of the light-emitting devices 801 may not be identical. Fore example, some of the light-emitting devices 801 may be configured to emit different color of light. However, each of the light-emitting devices 801 may have a reflector cup 814, a light source die 820, a first encapsulant 840, a light scattering member 842, and a second encapsulant 850. As shown in FIG. 8, the light source die 820 may be residing within the reflector cup 814. The first encapsulant 840 may be encapsulating the light source die 820, and at least a portion of the reflector cup 814. The second encapsulant 850 may be encapsulating entirely the first encapsulant 840 and the reflector cup 814. The light scattering member 842 may be optically coupled to the light source die 820 so as to scatter light. The light scattering member 842 may be provided between the light source die 820 and the second encapsulant 850.

Different aspects, embodiments or implementations may, but need not, yield one or more of the following advantages. For example, the size of the high-density layer may be critical in obtaining light uniformity. Although specific embodiments of the invention have been described and illustrated herein above, the invention should not be limited to any specific forms or arrangements of parts so described and illustrated. For example, light source die described above may be LEDs die or some other future light source die as known or later developed without departing from the spirit of the invention. Likewise, although light-emitting devices were discussed, the embodiments are applicable to optical devices such as proximity sensor and encoders as well as component level such as a light-source packaging to produce the light-emitting devices. The scope of the invention is to be defined by the claims appended hereto and their equivalents.

What is claimed is:

1. A light-emitting device, comprising:
a reflector cup having a top end;
a light source die positioned within the reflector cup and facing the top end;
a first encapsulant encapsulating at least the top end of the reflector cup and covering the light source die;
a light scattering member provided as part of the first encapsulant configured to scatter light emitted from the light source die; and
a second encapsulant that entirely encapsulates the first encapsulant and the reflector cup.

2. The light-emitting device of claim 1, wherein the light scattering member is integrally formed within the first encapsulant.

3. The light-emitting device of claim 1, wherein the light scattering member comprises scattered particles that are substantially uniformly distributed within the first encapsulant.

4. The light-emitting device of claim 1, wherein the light scattering member comprises a roughened surface of the first encapsulant.

5. The light-emitting device of claim 4, wherein the light scattering member further comprises air bubbles trapped on the roughened surface of the first encapsulant.

6. The light-emitting device of claim 1, wherein the first encapsulant comprises a lens surface, and wherein the light scattering member is formed on the lens surface.

7. The light-emitting device of claim 1, wherein the light scattering member comprises a plurality of reflective particles encapsulated within the first encapsulant.

8. The light-emitting device of claim 1, wherein the light scattering member comprises a plurality of metallic particles having irregular shapes so as to scatter light incident on the first encapsulant.

9. The light-emitting device of claim 1, wherein the light scattering member is encapsulated entirely within the first encapsulant.

10. The light-emitting device of claim 1, wherein the light scattering member comprises a high-density area and a low-density area, wherein the high-density area is configured to scatter light more as compared to of the low-density area of the light scattering member.

11. The light-emitting device of claim 10, wherein the high-density area is formed approximating the light source die at a center portion of the light scattering member.

12. The light-emitting device of claim 11, wherein the light source die comprises a light-emitting surface, and wherein the high-density area has an area substantially similar to an area of the light-emitting surface.

13. The light-emitting device of claim 11, wherein:
the reflector cup comprises an opening at the top end;
the light source die comprises a light-emitting surface; and
the high-density area has an area smaller than an area of the opening of the reflector cup but larger than an area of the light-emitting surface.

14. The light-emitting device of claim 1, wherein the second encapsulant comprises a lens surface configured to collimate light scattered by the light scattering member.

15. The light-emitting device of claim 14, wherein the light scattering member is formed between the lens surface and the light source die.

16. The light-emitting device of claim 14, wherein the reflector cup is configured to direct light such that light emitted from the light source die is visible within a first range of viewing angle, and wherein the light scattering member is configured to scatter light such that the light emitted from the light-emitting device is visible within a second range of viewing angle relatively larger than the first range of viewing angle.

17. A light-emitting device, comprising:
a reflector cup configured to direct light towards a first direction;
a light source die attached within the reflector cup;
a first encapsulant encapsulating the light source die and at least partially the reflector cup; and
a light scattering layer formed adjacent to the first encapsulant and facing the first direction; and
a second encapsulant surrounding the light scattering layer, the first encapsulant and the reflector cup.

18. The light-emitting device of claim 17, wherein the light scattering layer has a substantially uniform thickness.

19. The light-emitting device of claim 17, the first encapsulant comprises a substantially flat surface facing the first direction and in direct contact with the light scattering layer.

20. A display system, comprising:
a substrate; and
a plurality of light-emitting devices attached on a surface of the substrate, wherein each of the plurality of light-emitting devices comprises:
a reflector cup;
a light source die residing within the reflector cup;
a first encapsulant encapsulating the light source die, and at least a portion of the reflector cup;
a light scattering member optically coupled to the light source die; and
a second encapsulant encapsulating entirely the first encapsulant and the reflector cup, wherein the light scattering member is provided between the light source die and the second encapsulant.
